(19) United States
(12) Patent Application Publication
(10) Pub. No.: US 2012/0314389 A1
(43) Pub. Date: Dec. 13, 2012

(54) WIRING BOARD AND METHOD FOR MANUFACTURING SAME

(75) Inventor: Yoshinori TAKENAKA, Ogaki-shi (JP)

(73) Assignee: IBIDEN CO., LTD., Ogaki-shi (JP)

(21) Appl. No.: 13/424,420

(22) Filed: Mar. 20, 2012

Related U.S. Application Data
(60) Provisional application No. 61/467,697, filed on Mar. 25, 2011.

(51) Int. Cl. H05K 1/18; H05K 3/30; H05K 3/42; H05K 1/16; H05K 3/10

(52) U.S. Cl. 361/761; 174/260; 29/846; 29/852; 29/832

(57) ABSTRACT

A wiring board has a core structure having a first surface and a second surface on the opposite side of the first surface of the core structure, a first buildup structure formed on the first surface of the core structure and having insulation layers and conductive layers, and a second buildup structure formed on the second surface of the core structure and having insulation layers, conductive layers and an inductor device. The conductive layers in the second buildup structure include conductive patterns forming the inductor device, and one or more of the conductive patterns forming the inductor device has the thickness which is greater than the thicknesses of the conductive layers in the first buildup structure.

### CROSS-REFERENCE TO RELATED APPLICATIONS

The present application is based on and claims the benefit of priority to U.S. Application No. 61/467,697, filed Mar. 25, 2011, the entire contents of which are incorporated herein by reference.

### BACKGROUND OF THE INVENTION

1. Field of the Invention

The present invention relates to a wiring board and its manufacturing method.

2. Discussion of the Background

In Japanese Patent Application No. 2009-16504, a wiring board with a built-in spiral inductor is described. The contents of Japanese Laid-Open Patent Publication No. 2009-16504 are incorporated herein by reference in their entirety in this application.

### SUMMARY OF THE INVENTION

According to one aspect of the present invention, a wiring board has a core structure having a first surface and a second surface on the opposite side of the first surface of the core structure, a first buildup structure formed on the first surface of the core structure and having insulation layers and conductive layers, and a second buildup structure formed on the second surface of the core structure and having insulation layers, conductive layers and an inductor device. The conductive layers in the second buildup structure include conductive patterns forming the inductor device, and one or more of the conductive patterns forming the inductor device has the thickness which is greater than the thicknesses of the conductive layers in the first buildup structure.

According to another aspect of the present invention, a method for manufacturing a wiring board includes preparing a core structure, forming on a first surface of the core structure a first buildup structure having insulation layers and conductive layers, and forming on a second surface of the core structure on the opposite side of the first surface of the core structure a second buildup structure having insulation layers, conductive layers and an inductor device. The forming of the second buildup structure includes forming the conductive layers including conductive patterns forming the inductor device in the second buildup structure, and one or more of the conductive patterns forming the inductor device has the thickness which is greater than the thicknesses of the conductive layers in the first buildup structure.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view showing a wiring board according to an embodiment of the present invention;

FIG. 2 is a cross-sectional view showing a through-hole conductor according to the embodiment of the present invention;

FIG. 3 is a cross-sectional view showing measurements of each conductive layer, each insulation layer and each via conductor of a wiring board according to the embodiment of the present invention;

FIG. 4 is a cross-sectional view showing an inductor unit according to the embodiment of the present invention;

FIG. 5 is a perspective view showing the inductor unit according to the embodiment of the present invention;

FIG. 6 is a circuit diagram showing the inductor unit according to the embodiment of the present invention;

FIG. 7A is a perspective view showing a first inductor of the inductor unit according to the embodiment of the present invention;

FIG. 7B is a perspective view showing a second inductor of the inductor unit according to the embodiment of the present invention;

FIG. 8A is a view showing positioning of external connection terminals formed on an end of the inductor unit according to the embodiment of the present invention;

FIG. 8B is a view showing positioning of connection conductors (through-hole conductors) to be connected to the other end of the inductor unit according to the embodiment of the present invention;

FIG. 9 is a view showing an example of the circuit of an inductor built into a wiring board according to the embodiment of the present invention;

FIG. 10A is a view showing a first relationship between an inductor unit and the mounting region for an electronic component (projected region) in a wiring board according to the embodiment of the present invention;

FIG. 10B is a view showing a second relationship between inductor units and the mounting region for an electronic component (projected region) in a wiring board according to the embodiment of the present invention;

FIG. 10C is a view showing a third relationship between inductor units and the mounting regions for electronic components (projected regions) in a wiring board according to the embodiment of the present invention;

FIG. 11A is, directly under the mounting region of a wiring board according to the embodiment of the present invention, a view showing an example of conductive patterns in a conductive layer of a first buildup section;

FIG. 11B is, directly under the mounting region of a wiring board according to the embodiment of the present invention, a view showing an example of conductive patterns in a conductive layer of a second buildup section;

FIG. 12 is, in a method for manufacturing a wiring board according to the embodiment of the present invention, a view to illustrate a first step for forming the core section of a wiring board;

FIG. 13 is a view to illustrate a second step subsequent to the step in FIG. 12;

FIG. 14 is a view to illustrate a third step subsequent to the step in FIG. 13;

FIG. 15A is a view to illustrate a fourth step subsequent to the step in FIG. 14;

FIG. 15B is a view to illustrate another example of the fourth step for forming the core section of a wiring board according to the embodiment of the present invention;

FIG. 16 is a view to illustrate a fifth step subsequent to the step in FIG. 15A or FIG. 15B;

FIG. 17 is a view to illustrate a sixth step subsequent to the step in FIG. 16;

FIG. 18 is, in a method for manufacturing a wiring board according to the embodiment of the present invention, a view to illustrate a first step for forming first tiers in buildup sections of the wiring board;

FIG. 19 is a view to illustrate a second step subsequent to the step in FIG. 18;

FIG. 20 is a view to illustrate a third step subsequent to the step in FIG. 19;

FIG. 21 is a view to illustrate a fourth step subsequent to the step in FIG. 20;

FIG. 22 is a view to illustrate a fifth step subsequent to the step in FIG. 21;

FIG. 23 is a view to illustrate a sixth step subsequent to the step in FIG. 22;

FIG. 24 is, in a method for manufacturing a wiring board according to the embodiment of the present invention, a view to illustrate a step for forming second tiers in buildup sections of the wiring board;

FIG. 25 is, in a method for manufacturing a wiring board according to the embodiment of the present invention, a view to illustrate a step for forming third tiers in buildup sections of the wiring board;

FIG. 26 is, in a method for manufacturing a wiring board according to the embodiment of the present invention, a view to illustrate a step for forming fourth tiers in buildup sections of the wiring board;

FIG. 27 is, in a method for manufacturing a wiring board according to the embodiment of the present invention, a view to illustrate a step for forming fifth tiers in buildup sections of the wiring board;

FIG. 28A is a view to illustrate a first method for increasing the thickness of a conductive layer in a wiring board according to the embodiment of the present invention;

FIG. 28B is a view to illustrate a second method for increasing the thickness of a conductive layer in a wiring board according to the embodiment of the present invention;

FIG. 29 is a view to illustrate a method for decreasing the thickness of a conductive layer in a wiring board according to the embodiment of the present invention;

FIG. 30A is a view of a first structure showing conductive layers of a first buildup section and conductive layers of a second buildup section in the embodiment of the present invention;

FIG. 30B is a view of a second structure showing conductive layers of a first buildup section and conductive layers of a second buildup section in the embodiment of the present invention;

FIG. 30C is a view of a third structure showing conductive layers of a first buildup section and conductive layers of a second buildup section in the embodiment of the present invention;

FIG. 31 is a view of a fourth structure showing conductive layers of a first buildup section and conductive layers of a second buildup section in the embodiment of the present invention; and

FIG. 32 is a cross-sectional view showing an example of a wiring board having a different number of tiers in buildup sections on both surfaces (each main surface) of the core substrate in another embodiment of the present invention.

### DETAILED DESCRIPTION OF THE EMBODIMENTS

The embodiments will now be described with reference to the accompanying drawings, wherein like reference numerals designate corresponding or identical elements throughout the various drawings.

In the drawings, arrows (Z1, Z2) each indicate a lamination direction in a wiring board (or a direction of the thickness of the wiring board), corresponding to a direction along a normal line to the main surfaces (upper and lower surfaces) of the wiring board. On the other hand, arrows (X1, X2) and (Y1, Y2) each indicate a direction perpendicular to a lamination direction (or toward a side of each layer). The main surfaces of a wiring board are on the X-Y plane. Side surfaces of a wiring board are on the X-Z plane or the Y-Z plane. Unless otherwise specified, a planar shape means a shape on the X-Y plane. “Directly on” or “directly under” means along a direction Z (the Z1 side or the Z2 side).

Two main surfaces facing opposite directions of a normal line are referred to as a first surface (the Z1-side surface) and a second surface (the Z2-side surface). In lamination directions, the side closer to the core is referred to as a lower layer (or inner-layer side), and the side farther from the core is referred to as an upper layer (or outer-layer side). In a buildup section, a tier, a unit of which is a pair of an insulation layer and a conductive layer formed on the insulation layer, is formed by alternately laminating a conductive layer and an insulation layer (interlayer insulation layer). On both sides of a core substrate, an insulation layer and a conductive layer on the core substrate is referred to as a first tier, and further upper layers are consecutively referred to as a second tier, a third tier, and so forth.

Conductive layers indicate layers including one or more conductive patterns. A conductive layer may include a conductive pattern that forms an electrical circuit, wiring (including ground), a pad, a land or the like; or a conductive layer may include a plain conductive pattern that does not form an electrical circuit.

Opening portions include notches and cuts other than holes and grooves. Holes are not limited to penetrating holes, and may also be non-penetrating holes. Holes include via holes and through holes. Hereinafter, the conductor formed in a via hole (wall surface or bottom surface) is referred to as a via conductor, and the conductor formed in a through hole (wall surface) is referred to as a through-hole conductor.

Among the conductors formed in opening portions (such as via conductors and through-hole conductors), the conductive film formed on the inner surface (wall surface or bottom surface) of an opening portion is referred to as a conformal conductor, and the conductor filled in an opening portion is referred to as a filled conductor.

Plating includes wet plating such as electrolytic plating as well as dry plating such as PVD (physical vapor deposition) and CVD (chemical vapor deposition).

Unless otherwise specified, the “width” of a hole or a column (protrusion) indicates the diameter if it is a circle, and 2√ (cross section/π) if it is other than a circle. Also, when measurements are not uniform (for example, when the surface is roughened or the shape is tapered), basically, the average value of measurements (average of effective values excluding abnormal values) is used. However, if values such as a maximum value other than an average value are indicated to be used, the above definition does not apply.

A ring indicates a planar shape formed by connecting both ends of a line, and includes not only a circle but also a polygon.

“Alternately” includes situations in which two are positioned in proximity to each other.

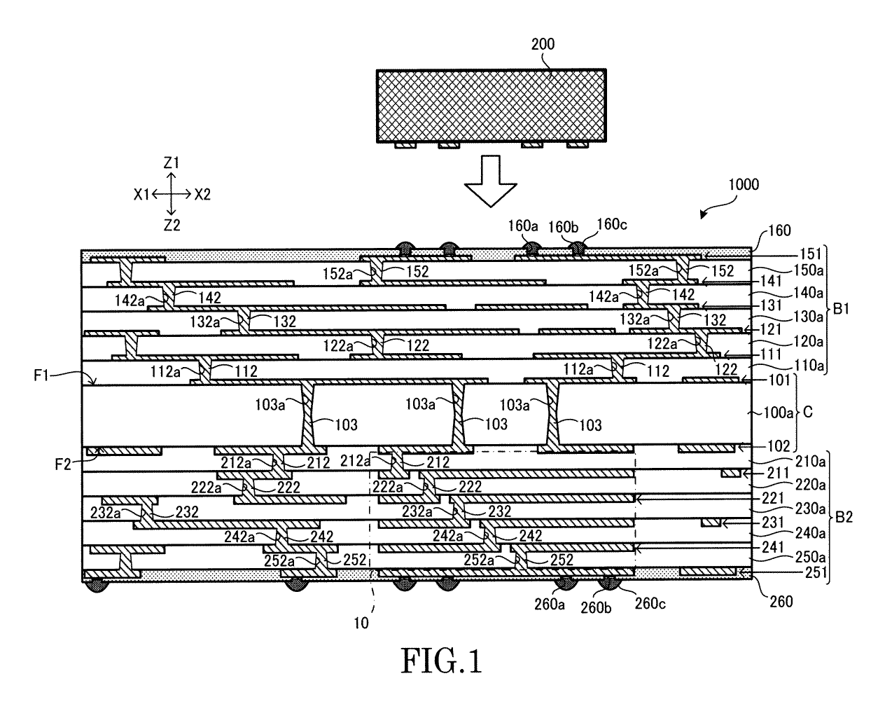

Wiring board 1000 of the present embodiment has core section (C), first buildup section (B1) and second buildup section (B2) as shown in FIG. 1. Electronic component 200, for example, is mounted on a surface of wiring board 1000. Electronic component 200 is formed with a semiconductor element, for example. However, electronic component 200 is not limited to such, and any other type may be mounted.

Core section (C) includes substrate (100a). Substrate (100a) is insulative, and corresponds to the core substrate of wiring board 1000. Substrate (100a) is made of epoxy resin, for example, more specifically, made by impregnating glass cloth (core material) with epoxy resin, for example. As for the core material, it is preferred to use inorganic material such as glass fiber or aramid fiber. However, the material for substrate (100a) (core substrate) is not limited to the above, and any other material may be used. For example, it may be resin other than epoxy resin, and it is an option not to include core material. Hereinafter, one of the upper and lower surfaces (two main surfaces) of substrate (100a) is referred to as first surface (F1) and the other as second surface (F2).

Core section (C) has conductive layer 101 on first surface (F1) of substrate (100a) and conductive layer 102 on second surface (F2) of substrate (100a). Conductive layers (101, 102) each include a land of through-hole conductor 103.

Through hole (103a) which penetrates through substrate (100a) is formed in substrate (100a) (core substrate). By filling conductor (such as conductor made of copper plating) in through hole (103a), through-hole conductor 103 is formed. A conductive pattern of conductive layer 101 and a conductive pattern of conductive layer 102 are electrically connected to each other by the conductor (through-hole conductor 103) in through hole (103a).

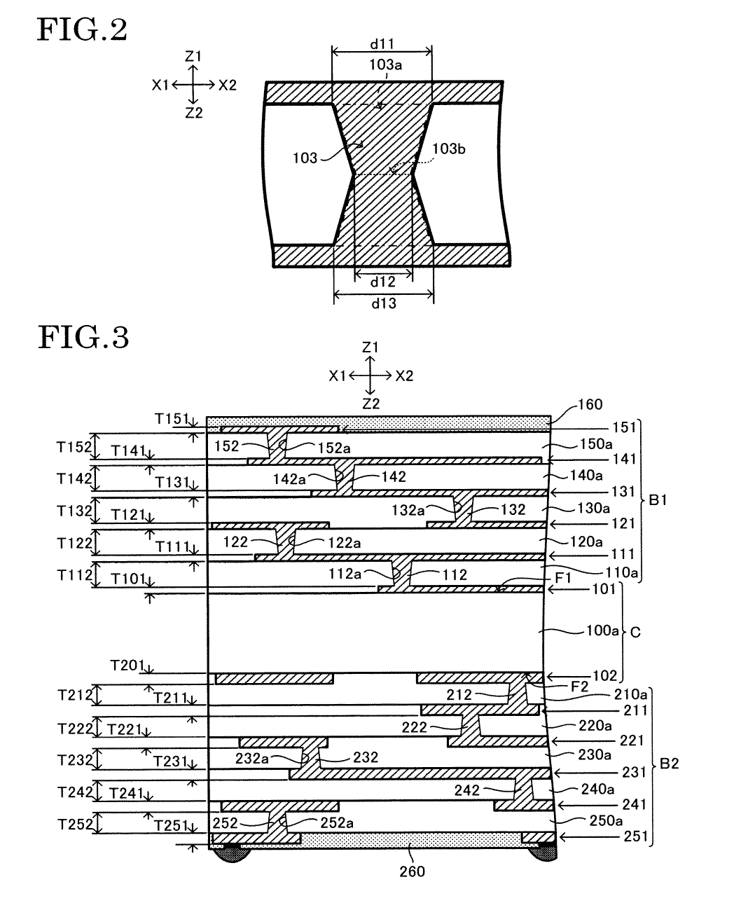

As shown in FIG. 2, for example, through-hole conductor 103 is shaped as an hourglass. Namely, through-hole conductor 103 has narrowed portion (103b), and the width of through-hole conductor 103 gradually decreases as it comes closer to narrowed portion (103b) from first surface (F1), and also gradually decreases as it comes closer to narrowed portion (103b) from second surface (F2). However, the shape of through-hole conductor 103 is not limited to such, and it may also be substantially a column, for example.

The width of the conductor in through hole (103a) (through-hole conductor 103) is preferred to be approximately 150 μm or less. Here, the width of through-hole conductor 103 means the maximum value (maximum width) of the width of through-hole conductor 103, corresponding to widths (d11, d13) at opening ends of the through hole in the present embodiment. Specifically, in the present embodiment, width (d11) at one end of through-hole conductor 103 is 100 μm, for example, width (d13) at the other end of through-hole conductor 103 is 100 μm, for example, and width (d12) at narrowed portion (103b) of through-hole conductor 103 is 70 μm, for example.

First buildup section (B1) is formed on first surface (F1) of substrate (100a), and second buildup section (B2) is formed on second surface (F2) of substrate (100a). First buildup section (B1) is formed by alternately laminating conductive layers (111, 121, 131, 141, 151) and insulation layers (110a, 120a, 130a, 140a, 150a); and second buildup section (B2) is formed by alternately laminating conductive layers (211, 221, 231, 241, 251) and insulation layers (210a, 220a, 230a, 240a, 250a). In the present embodiment, the number of tiers in first buildup section (B1) and the number of tiers in second buildup section (B2) are the same (five). More specifically, insulation layers (110a, 210a) and conductive layers (111, 211) form first tiers; insulation layers (120a, 220a) and conductive layers (121, 221) form second tiers; insulation layers (130a, 230a) and conductive layers (131, 231) form third tiers; insulation layers (140a, 240a) and conductive layers (141, 241) form fourth tiers; and insulation layers (150a, 250a) and conductive layers (151, 251) form fifth tiers.

Insulation layers (110a˜150a) and (210a˜250a) each correspond to an interlayer insulation layer. In the present embodiment, insulation layers (110a˜150a) (first insulation layers) and insulation layers (210a˜250a) (second insulation layers) each contain epoxy resin and inorganic filler. However, the material for each insulation layer is not limited to such and may be any other material. For example, resin other than epoxy resin may be used, and a core material may also be included.

First buildup section (B1) includes via conductors (112, 122, 132, 142, 152) (each a filled conductor) for interlayer connections, and second buildup section (B2) includes via conductors (212, 222, 232, 242, 252) (each a filled conductor) for interlayer connections. In particular, via holes (112a, 122a, 132a, 142a, 152a) are formed respectively in insulation layers (110a, 120a, 130a, 140a, 150a), and copper plating, for example, is filled in those via holes (112a) and the like to form via conductors (112, 122, 132, 142, 152). Also, via holes (212a, 222a, 232a, 242a, 252a) are formed respectively in insulation layers (210a, 220a, 230a, 240a, 250a), and copper plating, for example, is filled in those via holes (212a) and the like to form via conductors (212, 222, 232, 242, 252).

In each buildup section, conductive layers on different tiers (specifically, each conductive pattern on two vertically adjacent conductive layers) are electrically connected to each other by a conductor in a via hole (via conductor) formed in the interlayer insulation layer. More specifically, in first buildup section (B1), conductive layers (111, 121, 131, 141, 151) are electrically connected to each other by via conductors (122, 132, 142, 152) positioned in their respective interlayers. Also, in second buildup section (B2), conductive layers (211, 221, 231, 241, 251) are electrically connected to each other by via conductors (222, 232, 242, 252) positioned in their respective interlayers. In addition, conductive layer 111 is electrically connected to conductive layer 101 on substrate (100a) by via conductor 112, and conductive layer 211 is electrically connected to conductive layer 102 on substrate (100a) by via conductor 212. Via conductors (112˜152) and (212˜252) are each shaped to be a tapered column (truncated cone) tapering with a diameter decreasing toward substrate (100a), for example, and their planar shape is a perfect circle, for example. However, the shape of each via conductor is not limited to such, and may be any other shape.

FIG. 3 shows measurements of each conductive layer, each insulation layer and each via conductor.

In the present embodiment, conductive layers (211˜251) (second conductive patterns) are each thicker than any of conductive layers (111˜151) (first conductive patterns). In particular, thickness (T111) of conductive layer 111, thickness (T121) of conductive layer 121, thickness (T131) of conductive layer 131, thickness (T141) of conductive layer 141 and thickness (T151) of conductive layer 151 each have the same thickness (hereinafter referred to as (T1)), for example, in the range of 5˜20 μm. Also, thickness (T211) of conductive layer 211, thickness (T221) of conductive layer 221, thickness (T231) of conductive layer 231, thickness (T241) of conductive layer 241 and thickness (T251) of conductive layer 251 each have the same thickness (hereinafter referred to as (T2)), for example, in the range of 15˜30 μm. At that time, T2/T1 is in the range of approximately 1.5˜approximately 3. When T2/T1 is in such a range, the ratio of conductive layers (conductive patterns) in each buildup section is in a required range, and the warping of the wiring board is effectively suppressed. Moreover, desired inductance is easily secured.

Thickness (T101) of conductive layer 101 is thicker than conductive layers 111 and the like in first buildup section (B1). Also, thickness (T201) of conductive layer 102 is thicker than conductive layers 211 and the like in second buildup section (B2).

When the tiers in the same ordinal number are compared, the conductive layer in second buildup section (B2) is thicker than the conductive layer in first buildup section (B1) in all the tiers. Specifically, the following are satisfied: thickness (T111)<thickness (T211), thickness (T121)<thickness (T221), thickness (T131)<thickness (T231), thickness (T141)<thickness (T241), and thickness (T151)<thickness (T251).

Each of insulation layers (110a˜150a) (first insulation layers) and each of insulation layers (210a˜250a) (second insulation layers) all have the same thickness. Specifically, each of the following has the same thickness, for example, in the range of 20˜30 μm: thickness (T112) of insulation layer (110a), thickness (T122) of insulation layer (120a), thickness (T132) of insulation layer (130a), thickness (T142) of insulation layer (140a), thickness (T152) of insulation layer (150a), thickness (T212) of insulation layer (210a), thickness (T222) of insulation layer (220a), thickness (T232) of insulation layer (230a), thickness (T242) of insulation layer (240a) and thickness (T252) of insulation layer (250a). Here, the above thickness of an insulation layer indicates the distance of adjacent conductive patterns in a direction Z.

Conductors (via conductors 212˜252) in the via holes formed in interlayer insulation layers (second insulation layers) in second buildup section (B2) are each thinner than any of the conductors (via conductors 112˜152) in the via holes formed in interlayer insulation layers (first insulation layers) in first buildup section (B1).

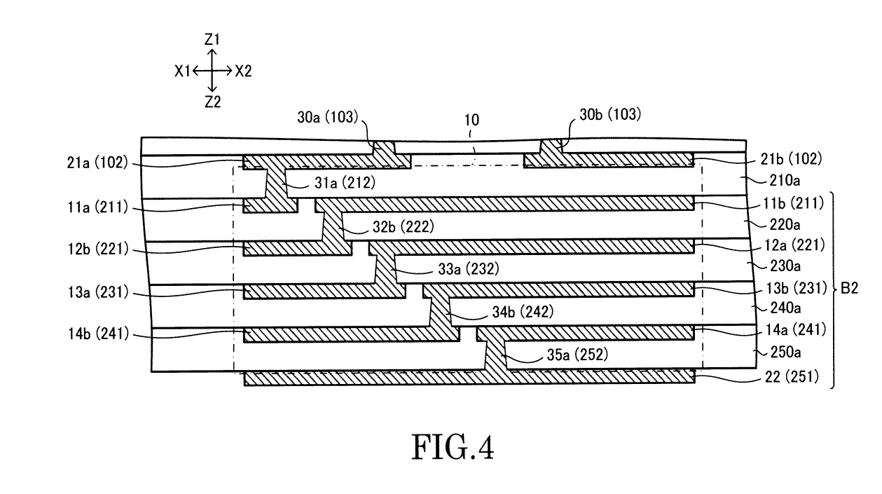

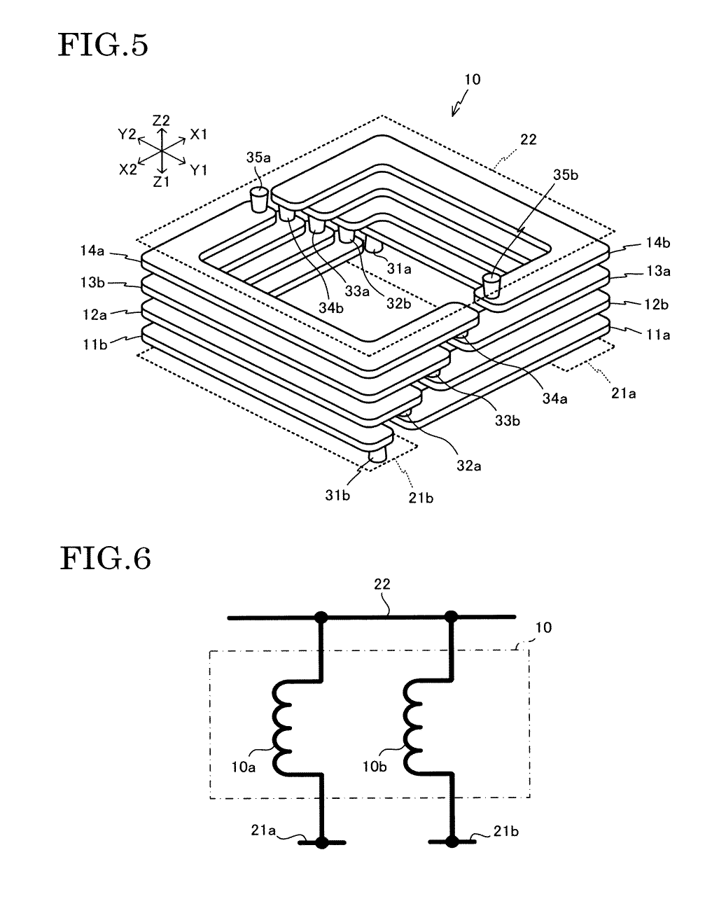

Inductor unit 10 (inductor section) is built into wiring board 1000 of the present embodiment. In the following, the structure of inductor unit 10 is described with reference to FIGS. 4˜7. In each drawing, conductive patterns (21a, 21b) are included in conductive layer 102, conductive patterns (11a, 11b) are included in conductive layer 211, conductive patterns (12a, 12b) are included in conductive layer 221, conductive patterns (13a, 13b) are included in conductive layer 231, conductive patterns (14a, 14b) are included in conductive layer 241, and conductive pattern 22 is included in conductive layer 251. Connection conductors (30a, 30b) correspond to through-hole conductors 103, connection conductors (31a, 31b) correspond to via conductors 212, connection conductors (32a, 32b) correspond to via conductors 222, connection conductors (33a, 33b) correspond to via conductors 232, connection conductors (34a, 34b) correspond to via conductors 242, and connection conductors (35a, 35b) correspond to via conductors 252. As shown in FIGS. 4˜7B, in inductor unit 10 of the present embodiment, four layers of conductive patterns (11a˜14a) and (11b˜14b) make multiple (such as two) one-turn inductors. Specifically, inductor unit 10 includes first inductor (10a) and second inductor (10b). As shown in FIG. 6, first inductor (10a) and second inductor (10b) are connected parallel to each other.

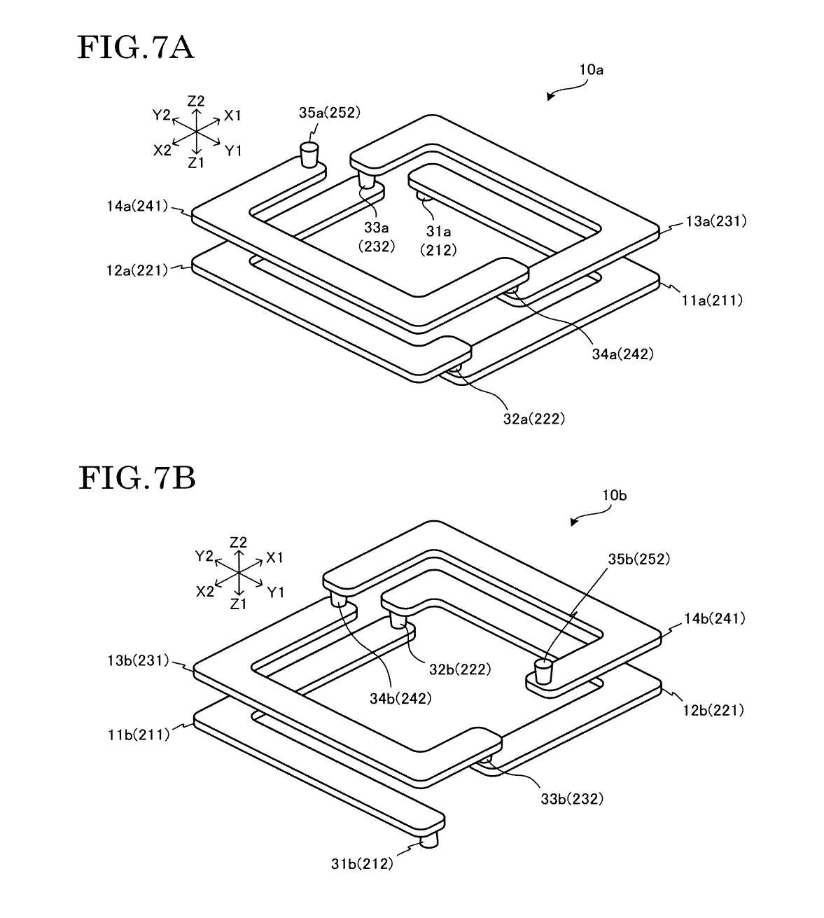

As shown in FIGS. 4 and 7A, first inductor (10a) is formed with the conductors in second buildup section (B2), in particular, connection conductors (31a˜35a) (via conductors 212˜252), and with conductive patterns (11a˜14a) of conductive layers (211˜241) electrically connected to each other by connection conductors (32a˜34a). Also, as shown in FIGS. 4 and 7B, second inductor (10b) is formed with the conductors in second buildup section (B2), in particular, connection conductors (31b˜35b) (via conductors 212˜252), and with conductive patterns (11b˜14b) of conductive layers (211˜241) electrically connected to each other by connection conductors (32b˜34b).

Conductive layers (211˜241) including the conductive patterns that form inductor unit 10 (first inductor (10a) and second inductor (10b)) are each thicker than any of conductive layers (111˜151) as described above (see FIG. 3). Conductors in via holes (via conductors 222˜242) electrically connecting the conductive patterns of conductive layers (211˜241) of inductor unit 10 (first inductor (10a) and second inductor (10b)) are each thinner than any of the conductors (via conductors 112˜152) in via holes formed in insulation layers (110a˜150a) (first insulation layers) (see FIG. 3).

In the present embodiment, first inductor (10a) and second inductor (10b) are each shaped in a spiral form and are substantially annular (more specifically, substantially rectangular) in a plan view as shown in FIGS. 7A and 7B.

Conductive patterns (11a˜14a) and (11b˜14b) of inductor unit 10 (first inductor (10a) and second inductor (10b)) are each made of a substantially U-shaped or substantially L-shaped conductor. A pair of conductive patterns positioned on different tiers and electrically connected to each other by the conductor in a via hole (connection conductors (32a˜34a) and (32b˜34b)) are each formed to be substantially U-shaped or substantially L-shaped and substantially facing each other. Specifically, in first inductor (10a), a pair of conductive patterns (11a) and (12a), a pair of conductive patterns (12a) and (13a) and a pair of conductive patterns (13a) and (14a) are each formed to be substantially U-shaped or substantially L-shaped and substantially facing each other as shown in FIG. 7A. Also, in second inductor (10b), a pair of conductive patterns (11b) and (12b), a pair of conductive patterns (12b) and (13b) and a pair of conductive patterns (13b) and (14b) are each formed to be substantially U-shaped or substantially L-shaped and substantially facing each other as shown in FIG. 7B.

In first inductor (10a), as shown in FIG. 7A, an end of substantially L-shaped conductive pattern (11a) is connected to an end of substantially L-shaped conductive pattern (12a) by connection conductor (32a), the other end of conductive pattern (12a) is connected to an end of substantially U-shaped conductive pattern (13a) by connection conductor (33a), and the other end of conductive pattern (13a) is connected to an end of substantially U-shaped conductive pattern (14a) by connection conductor (34a). Also, connection conductor (31a) is formed at the other end of conductive pattern (11a) (the end not connected to conductive pattern (12a)), and connection conductor (35a) is formed on the other end of conductive pattern (14a) (the end not connected to conductive pattern (13a)).

In doing so, by conductive patterns (11a˜14a) connected to each other in series, two-turn first inductor (10a) is formed in the present embodiment.

In second inductor (10b), as shown in FIG. 7B, an end of substantially L-shaped conductive pattern (11b) is connected to an end of substantially L-shaped conductive pattern (12b) by connection conductor (32b), the other end of conductive pattern (12b) is connected to an end of substantially U-shaped conductive pattern (13b) by connection conductor (33b), and the other end of conductive pattern (13b) is connected to an end of substantially U-shaped conductive pattern (14b) by connection conductor (34b). Also, connection conductor (31b) is formed at the other end of conductive pattern (11b) (the end not connected to conductive pattern (12b)), and connection conductor (35b) is formed on the other end of conductive pattern (14b) (the end not connected to conductive pattern (13b)). In doing so, by conductive patterns (11b˜14b) connected to each other in series, two-turn second inductor (10b) is formed in the present embodiment.

As shown in FIGS. 4˜6, conductive pattern (11a) of first inductor (10a) is connected to conductive pattern (21a) of conductive layer 102 by connection conductor (31a), and conductive pattern (11b) of second inductor (10b) is connected to conductive pattern (21b) of conductive layer 102 by connection conductor (31b). Conductive pattern (14a) of first inductor (10a) and conductive pattern (14b) of second inductor (10b) are connected to conductive pattern 22 by connection conductor (35a) and connection conductor (35b) respectively. First inductor (10a) and second inductor (10b) are electrically connected to each other by conductive pattern 22 (see FIG. 6).

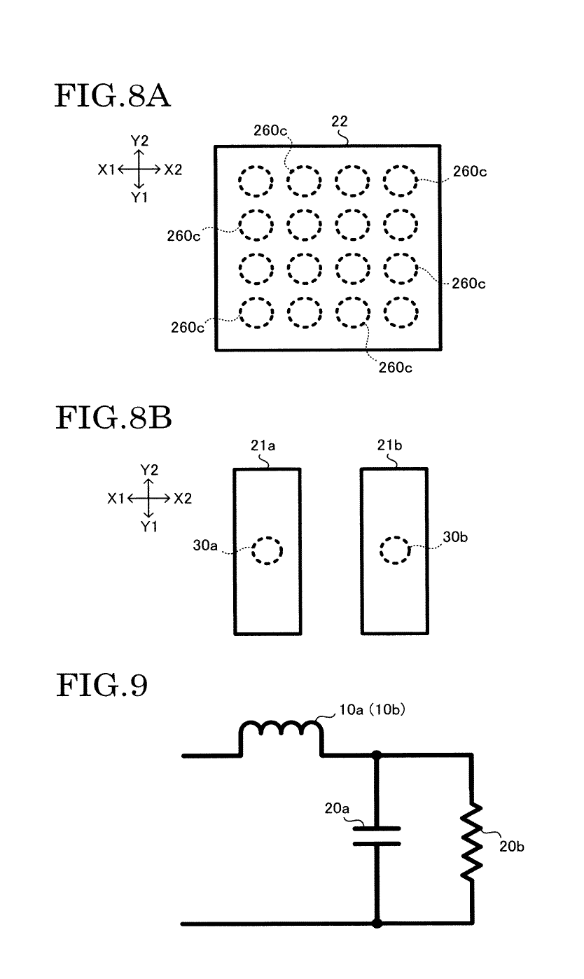

As shown in FIG. 8A, for example, a required number of solder bumps (260c) (external connection terminals) are formed on conductive pattern 22 (substantially the entire surface, for example). Also, as shown in FIG. 8B, for example, connection conductor (30a) (through-hole conductor 103) is connected to conductive pattern (21a) of conductive layer 102, and connection conductor (30b) (through-hole conductor 103) is connected to conductive pattern (21b) of conductive layer 102. Through-hole conductors 103 with a small diameter are connected to first inductor (10a) and second inductor (10b), and the L value of inductor unit 10 (inductor section) tends to be improved.

First inductor (10a) or second inductor (10b) forms a smoothing circuit by being connected to capacitor (20a) and resistance element (20b) as shown in FIG. 9, for example. Capacitor (20a) and resistance element (20b) are formed in first buildup section (B1) or second buildup section (B2), for example. Accordingly, voltage is smoothed near electronic component 200 (FIG. 1), and loss of power supply for electronic component 200 tends to be reduced. Capacitor (20a) and resistance element (20b) may be mounted on a surface of wiring board 1000 as electronic component 200 (see FIG. 1).

As shown in FIG. 1, conductive layer 151 is the outermost conductive layer on the first-surface (F1) side, and conductive layer 251 is the outermost conductive layer on the second-surface (F2) side in wiring board 1000 of the present embodiment. Solder resists (160, 260) are formed respectively on conductive layers (151, 251). However, opening portions (160a, 260a) are formed respectively in solder resists (160, 260). Anticorrosion layer (160b) is formed on conductive layer 151 exposed through opening portion (160a), and anticorrosion layer (260b) is formed on conductive layer 251 exposed through opening portion (260a).

In the present embodiment, anticorrosion layers (160b, 260b) are each made of Ni/Pd/Au film, for example. Anticorrosion layers (160b, 260b) are formed by electroless plating, for example. Also, by conducting an OSP treatment, anticorrosion layers (160b, 260b) may be formed with organic protective film. Anticorrosion layers (160b, 260b) are not always required, and they may be omitted unless necessary.

Solder bump (160c) is formed on anticorrosion layer (160b), and solder bump (260c) is formed on anticorrosion layer (260b). Solder bump (160c) becomes an external connection terminal for mounting electronic component 200 (FIG. 1), for example, and solder bump (260c) becomes an external connection terminal for electrical connection with another wiring board (such as a motherboard), for example. However, the usage of solder bumps (160c, 260c) is not limited to such, and they may be used for any other purposes.

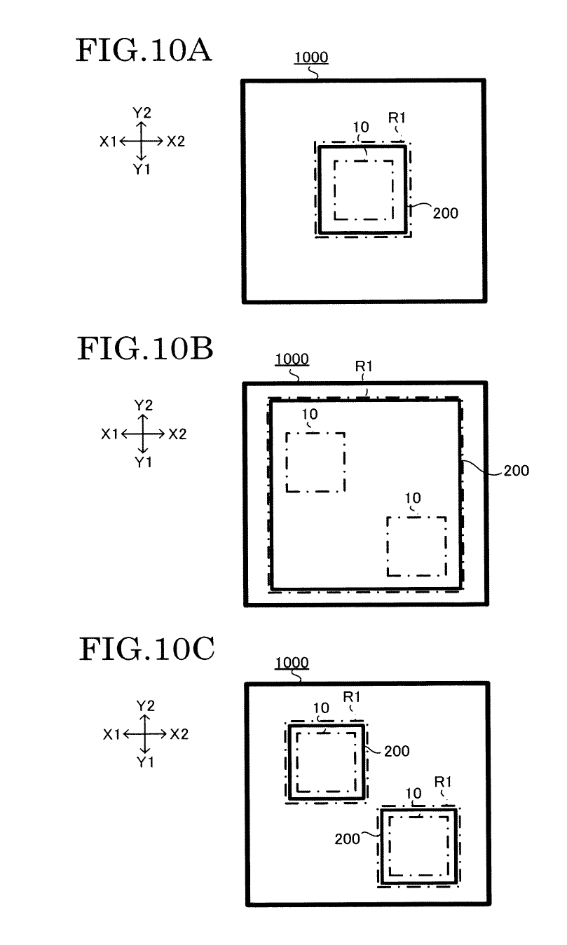

As shown in FIGS. 1 and 10A, wiring board 1000 of the present embodiment has a region for mounting electronic component 200 (mounting region R1) on one surface (the first-surface (F1) side, for example). Inductor unit 10 (first inductor (10a) and second inductor (10b)) is positioned directly under mounting region (R1) (the projected region of electronic component 200). FIG. 10A shows an example in which one inductor unit 10 is positioned directly under one mounting region (R1). However, the present embodiment is not limited to such. For example, as shown in FIG. 10B, two inductor units 10 may be positioned directly under one mounting region (R1). Alternatively, as shown in FIG. 10C, multiple (such as two) mounting regions (R1) are formed at least on one surface of wiring board 1000, and inductor unit 10 is positioned directly under each mounting region (R1).

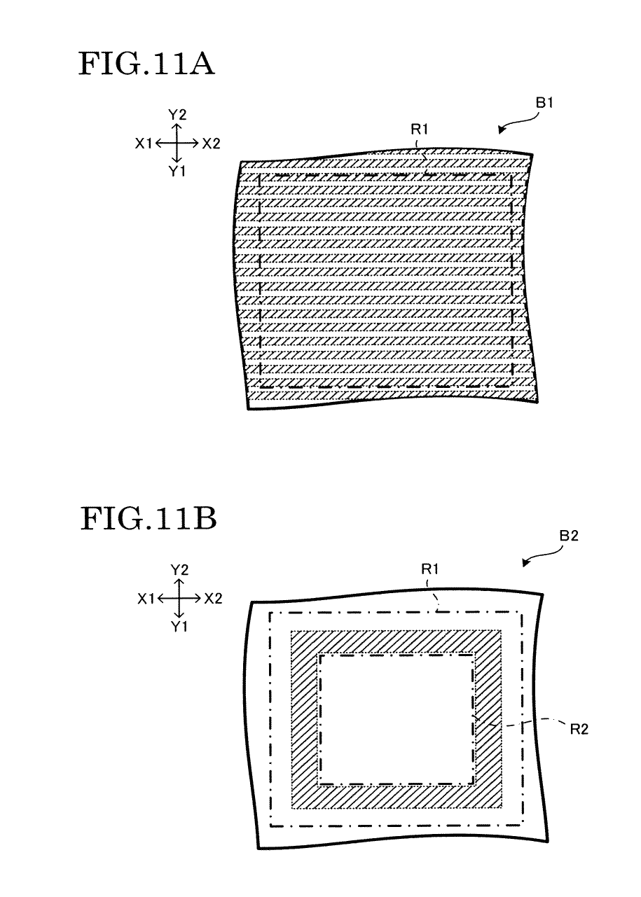

FIG. 11A shows an example of the conductive pattern of a conductive layer in first buildup section (B1) directly under mounting region (R1) (the projected region of electronic component 200), and FIG. 11B shows an example of the conductive pattern of a conductive layer in second buildup section (B2) directly under mounting region (R1) (the projected region of electronic component 200).

Directly under mounting region (R1), conductive patterns of conductive layers (111˜151) in first buildup section (B1) form mainly wiring, having L (line)/S (space) of 9 μm/12 μm, for example, as shown in FIG. 11A.

Directly under mounting region (R1), conductive patterns of conductive layers (211˜241) in second buildup section (B2) form mainly inductor unit 10 (first inductor (10a) and second inductor (10b)) as shown in FIG. 11B. In region (R2) positioned inside spiral first inductor (10a) and second inductor (10b), conductive patterns are not arranged, and resin is filled (insulation layers (220a˜240a)). Accordingly, directly under mounting region (R1), the abundance ratio per unit area on the X-Y plane is greater in conductive layers layers (111˜151) than in conductive layers (211˜251). In the present embodiment, since conductive layers (211˜251) are each thicker than any of conductive layers (111˜151) (see FIG. 3), the abundance ratio per unit thickness in a direction Z is greater in conductive layers (211˜251) than in conductive layers (111˜151). Accordingly, directly under mounting region (R1) (projected region of electronic component 200), when the ratio (volume ratio) of conductive layers (111˜151) in first buildup section (B1) is set as (W1), and the ratio (volume ratio) of conductive layers (211˜251) in second buildup section (B2) is set as (W2), W2/W1 is in the range of approximately 0.9 to approximately 1.2. As a result, the degree of thermal contraction becomes substantially the same in first buildup section (B1) and in second buildup section (B2), and wiring board 1000 seldom warps. Then, it is easier to mount electronic component 200 on wiring board 1000.

To bring the ratio W2/W1 closer to 1, it is an option that the abundance ratio of the conductive layers in first buildup section (B1) on the X-Y plane is made substantially the same as the abundance ratio of the conductive layers in second buildup section (B2) (see FIG. 11B). However, such a method may result in new problems such as lowered design flexibility and difficulty in securing wiring space. For that matter, according to the above structure of the present embodiment, design flexibility is maintained highly and wiring space is secured easily.

Wiring board 1000 of the present embodiment may be electrically connected to an electronic component or another wiring board, for example. As shown in FIG. 1, for example, electronic component 200 (such as an IC chip) is mounted on pads on one side of wiring board 1000 through soldering or the like. Also, using pads on the other side, wiring board 1000 is mounted on another wiring board (such as a motherboard) which is not shown in the drawings. Wiring board 1000 of the present embodiment is used as a circuit board for cell phones, compact computers and the like.

Wiring board 1000 of the present embodiment is manufactured by the following method, for example.

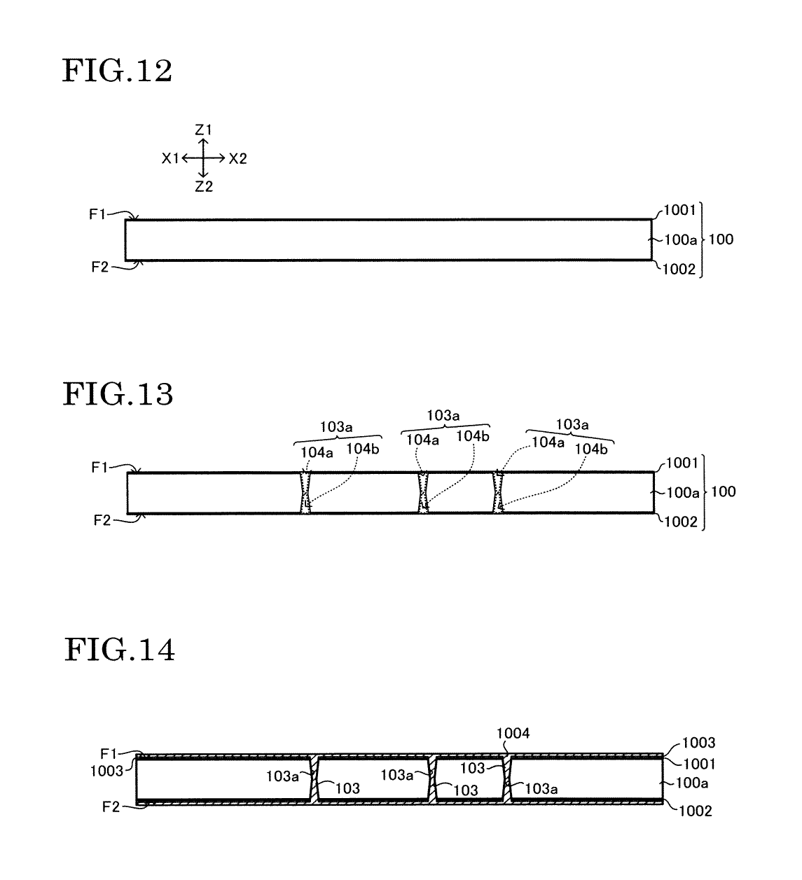

First, as shown in FIG. 12, double-sided copper-clad laminate 100 is prepared. Double-sided copper-clad laminate 100 is formed with substrate (100a) (core substrate) having first surface (F1) and an opposite second surface (F2), copper foil 1001 formed on first surface (F1) of substrate (100a), and copper foil 1002 formed on second surface (F2) of substrate (100a). Substrate (100a) is made by impregnating glass cloth (core material) with epoxy resin, for example.

Next, as shown in FIG. 13, using a CO₂ laser, for example, hole (104a) is formed by irradiating the laser at double-sided copper-clad laminate 100 from the first-surface (F1) side, and hole (104b) is formed by irradiating the laser at double-sided copper-clad laminate 100 from the second-surface (F2) side. Hole (104a) and hole (104b) are connected later to be hourglass-shaped through hole (103a) which penetrates through double-sided copper-clad laminate 100 (see FIG. 2). The boundary of hole (104a) and hole (104b) corresponds to narrowed portion (103b) (FIG. 2). Laser irradiation at first surface (F1) and laser irradiation at second surface (F2) may be conducted simultaneously or separately one surface at a time. After through hole (103a) is formed, desmearing is preferred to be conducted at through hole (103a). Unnecessary conduction (short circuiting) is suppressed by desmearing. Also, prior to laser irradiation, a black-oxide treatment may be conducted on the surfaces of copper foils (1001, 1002) to enhance the efficiency of laser absorption. Instead of laser irradiation, drilling, etching or the like may be employed to form through hole (103a). However, it is easier to perform fine processing by using a laser.

Next, using a panel plating method, for example, electroless copper-plated film 1003 and electrolytic copper plating 1004, for example, are formed on copper foils (1001, 1002) and in through hole (103a) as shown in FIG. 14. Specifically, electroless plating is first performed to form electroless plated film 1003. Then, using electroless plated film 1003 as a seed layer, electrolytic plating is performed using a plating solution to form electrolytic plating 1004. Accordingly, through hole (103a) is filled with electroless plated film 1003 and electrolytic plating 1004, and through-hole conductor 103 is formed. To enhance adhesion of electroless plated film 1003, a catalyst whose main ingredient is palladium (Pd), for example, may be attached to the wall surface or the like of through hole (103a) prior to electroless plating.

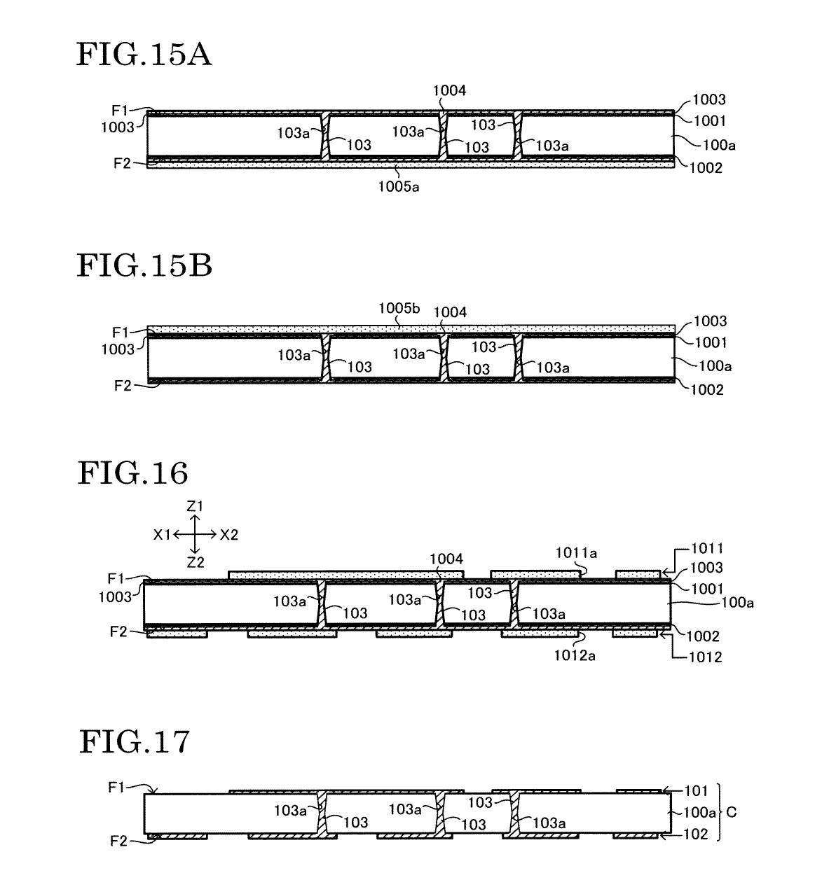

Next, as shown in FIG. 15A, while the surface of electrolytic plating 1004 on the second-surface (F2) side is covered by etching resist (105a), electrolytic plating 1004 on the first-surface (F1) side is made thinner by etching, for example. In doing so, the conductive layer on second surface (F2) of substrate (100a) becomes thicker than the conductive layer on first surface (F1) of substrate (100a).

The method to differentiate the thickness of the conductive layers between first buildup section (B1) and second buildup section (B2) is not limited to etching, and any other method may be employed. For example, as shown in FIG. 15B, while the surface of electrolytic plating 1004 on the first-surface (F1) side is covered by plating resist (105b), additional electrolytic plating or the like is performed on the surface of electrolytic plating 1004 on the second-surface (F2) side to make it thicker.

Next, using etching resists (1011, 1012), for example, as shown in FIG. 16, conductive layers formed respectively on first surface (F1) and second surface (F2) of substrate (100a) are patterned. Specifically, conductive layers are covered by their respective etching resists (1011, 1012) having patterns corresponding respectively to conductive layers (101, 102) (see FIG. 17). Then, portions of each conductive layer not covered by etching resists (1011, 1012) (portions exposed through opening portions (1011a, 1012a) of etching resists (1011, 1012)) are removed by wet or dry etching. Accordingly, conductive layers (101, 102) are formed respectively on first surface (F1) and second surface (F2) of substrate (100a) as shown in FIG. 17. As a result, core section (C) formed with substrate (100a) and conductive layers (101, 102) is completed. In the present embodiment, conductive layers (101, 102) are each made of copper foil, electroless copper plating and electrolytic copper plating. Also, since the thickness is adjusted prior to patterning, conductive layer 102 on second surface (F2) of substrate (100a) is thicker than conductive layer 101 on first surface (F1) of substrate (100a) (see FIG. 15A).

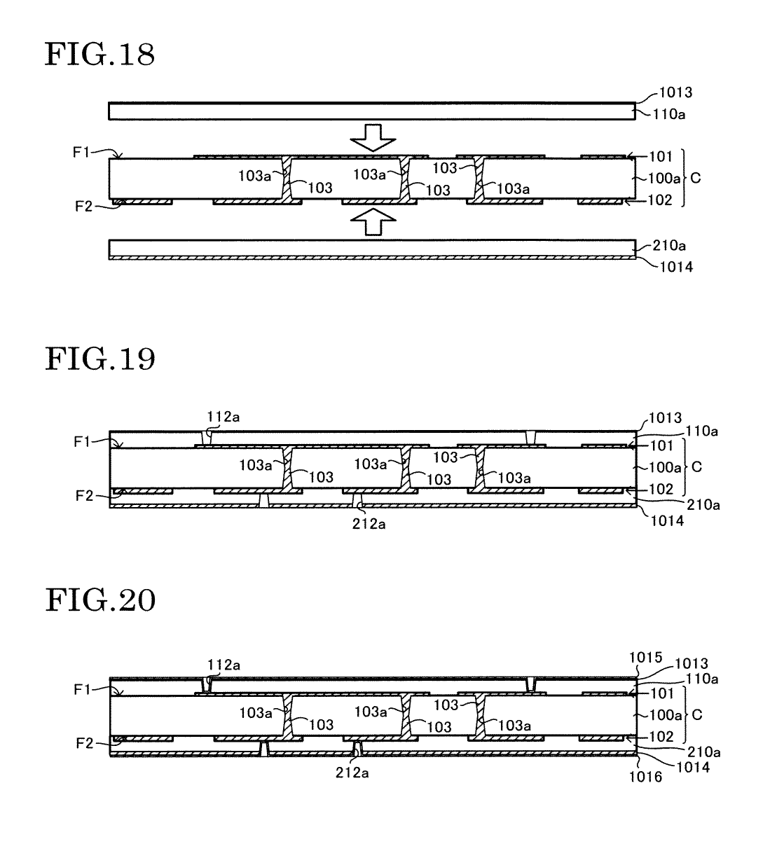

Next, through lamination, for example, insulation layer (110a) having copper foil 1013 on one surface (resin-coated copper foil) is pressed onto first surface (F1) of substrate (100a), and insulation layer (210a) having copper foil 1014 on one surface (resin-coated copper foil) is pressed onto second surface (F2) of substrate (100a) as shown in FIG. 18.

In the present embodiment, copper foil 1014 is thicker than copper foil 1013.

Next, using a laser, for example, via hole (112a) is formed in insulation layer (110a) and copper foil 1013, and via hole (212a) is formed in insulation layer (210a) and copper foil 1014 as shown in FIG. 19. Via hole (112a) reaches conductive layer 101, and via hole (212a) reaches conductive layer 102. Then, desmearing is conducted if required.

Next, by a chemical plating method, for example, electroless copper-plated films (1015, 1016) are formed on copper foils (1013, 1014) and in via holes (112a, 212a) as shown in FIG. 20. Prior to electroless plating, a catalyst made of palladium or the like may be adsorbed on surfaces of insulation layers (110a, 210a) and the like through immersion, for example.

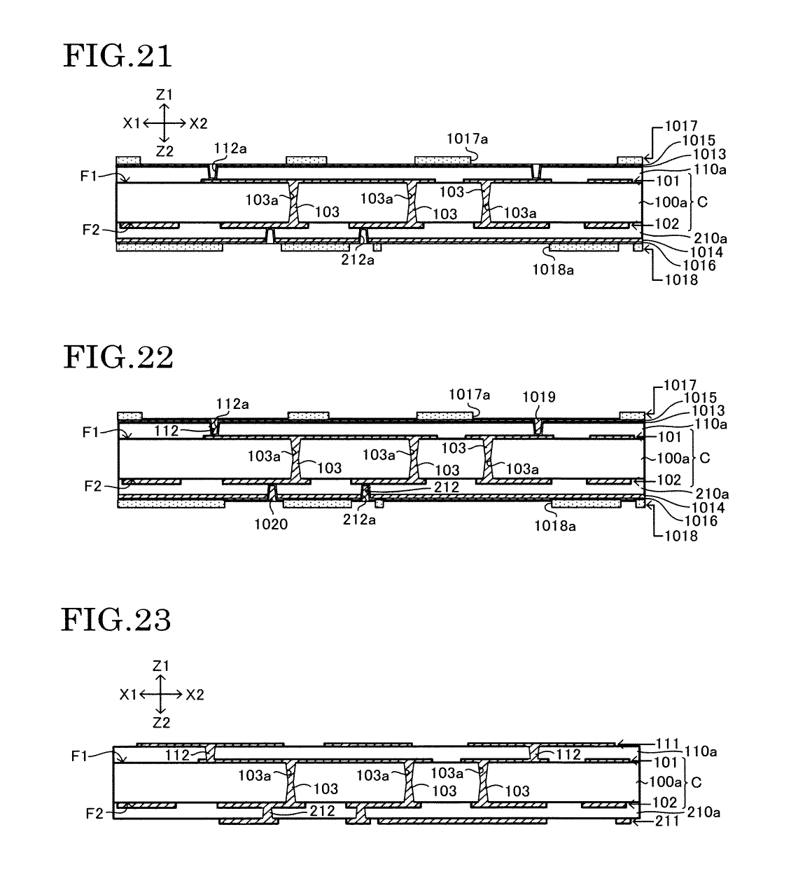

Next, using a lithographic technique, printing or the like, plating resist 1017 with opening portion (1017a) is formed on electroless plated film 1015, and plating resist 1018 with opening portion (1018a) is formed on electroless plated film 1016 as shown in FIG. 21. Opening portions (1017a, 1018a) correspond to their respective patterns of conductive layers (111, 211) (see FIG. 23).

Next, using a pattern plating method, for example, electrolytic copper platings (1019, 1020), for example, are formed respectively in opening portions (1017a, 1018a) of plating resists (1017, 1018) as shown in FIG. 22. Specifically, copper as the plating material is connected to the anode, and electroless plated films (1015, 1016) as the material to be plated are connected to the cathode, and are then immersed in a plating solution. Then, DC voltage is applied between the poles to flow electric current, depositing copper on the surfaces of electroless plated films (1015, 1016). Accordingly, via holes (112a, 212a) are filled respectively with electrolytic platings (1019, 1020). Via conductors (112, 212) made of copper plating, for example, are formed.

Then, using a predetermined removing solution, for example, plating resists (1017, 1018) are removed. After that, by removing unnecessary portions of electroless plated films (1015, 1016) and copper foils (1013, 1014), conductive layers (111, 211) are formed as shown in FIG. 23. As a result, first tiers are completed in first buildup section (B1) and second buildup section (B2). Since copper foil 1014 is thicker than copper foil 1013 in the present embodiment (see FIG. 18), conductive layer 211 is thicker than conductive layer 111. The thickness of conductive layer 211 is in the range of 15˜30 μm, and the thickness of conductive layer 111 is in the range of 5˜20 μM. The thicknesses of copper foils (1013, 1014) are set so as to set the thicknesses of conductive layer 211 and conductive layer 111 in the above ranges. The copper foil thicknesses are set the same in the following.

The material for electroless plated films (1015, 1016) is not limited to copper, and nickel, titanium or chrome may be used, for example. Also, a seed layer for electrolytic plating is not limited to electroless plated film, and sputtered film, CVD film or the like may also be used as a seed layer instead of electroless plated films (1015, 1016).

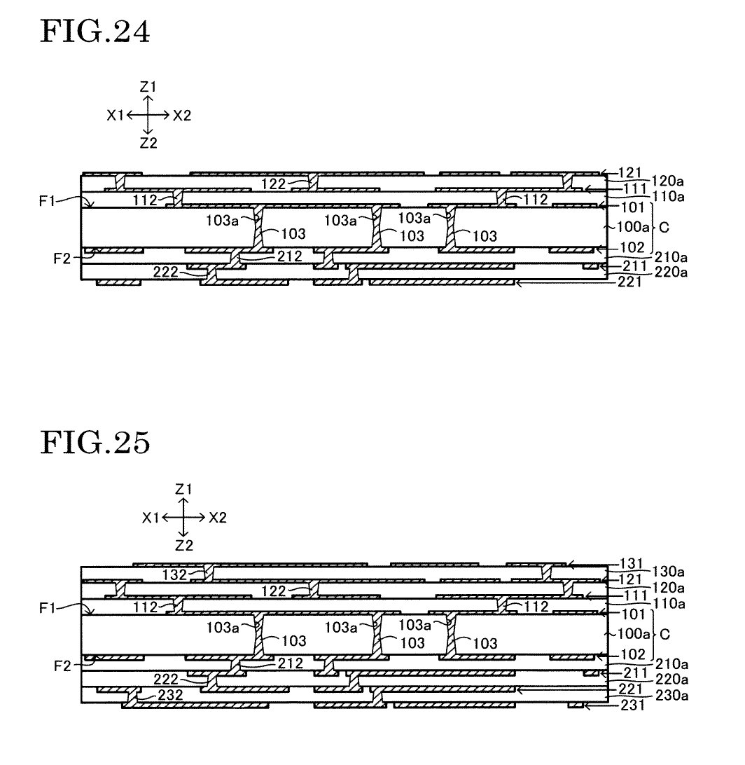

Next, the same as the first tiers, second tiers are formed in first buildup section (B1) and second buildup section (B2) as shown in FIG. 24. The same as in the first tiers, conductive layer 221 is also made thicker than conductive layer 121 in the second tiers by differentiating the thicknesses of the copper foils, for example.

Next, the same as the first tiers, third tiers are formed in first buildup section (B1) and second buildup section (B2) as shown in FIG. 25. The same as in the first tiers, conductive layer 231 is also made thicker than conductive layer 131 in the third tiers by differentiating the thicknesses of the copper foils, for example (see FIG. 18).

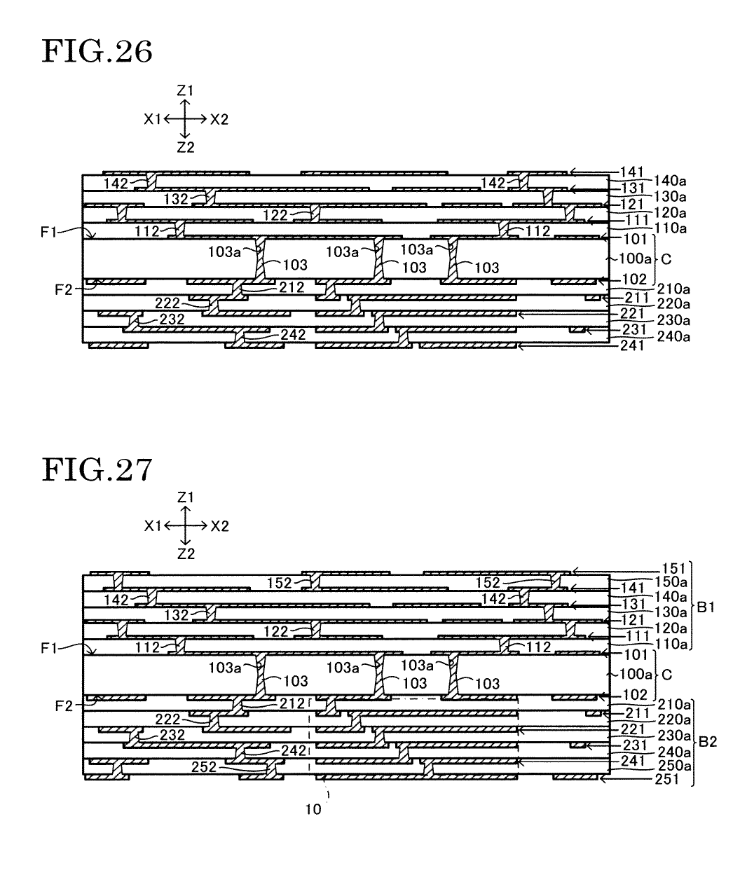

Next, the same as the first tiers, the fourth tiers are formed in first buildup section (B1) and second buildup section (B2) as shown in FIG. 26. The same as in the first tiers, conductive layer 241 is also made thicker than conductive layer 141 in the fourth tiers by differentiating the thicknesses of the copper foils, for example (see FIG. 18).

Next, the same as the first tiers, the fifth tiers are formed in first buildup section (B1) and second buildup section (B2) as shown in FIG. 27. The same as in the first tiers, conductive layer 251 is also made thicker than conductive layer 151 in the fifth tiers by differentiating the thicknesses of the copper foils, for example (see FIG. 18).

In the present embodiment, when first through fifth tiers are formed in second buildup section (B2), the conductors in second buildup section (B2) form inductor unit 10 (first inductor (10a) and second inductor (10b)) (see FIGS. 4˜7B).

Next, solder resist 160 having opening portion (160a) is formed on insulation layer (150a), and solder resist 260 having opening portion (260a) is formed on insulation layer (250a) (see FIG. 1). Conductive layers (151, 251) are respectively covered by solder resists (160, 260) except for locations (such as pads) corresponding to opening portions (160a, 260a). Solder resists (160, 260) are formed by screen printing, spray coating, roll coating, lamination or the like, for example.

Next, by sputtering or the like, anticorrosion layers (160b, 260b) made of Ni/Au film, for example, are formed on conductive layers (151, 251), more specifically, on surfaces of pads not covered by solder resists (160, 260) (see FIG. 1). Also, by conducting an OSP treatment, anticorrosion layers (160b, 260b) may be formed with organic protective film.

Through the above procedures, wiring board 1000 of the present embodiment (FIG. 1) is completed. Then, electrical testing is performed if required.

The manufacturing method according to the present embodiment is suitable for manufacturing wiring board 1000. An excellent wiring board 1000 is obtained at low cost using such a manufacturing method.

An embodiment of the present invention has been described as above. However, the present invention is not limited to the above embodiment.

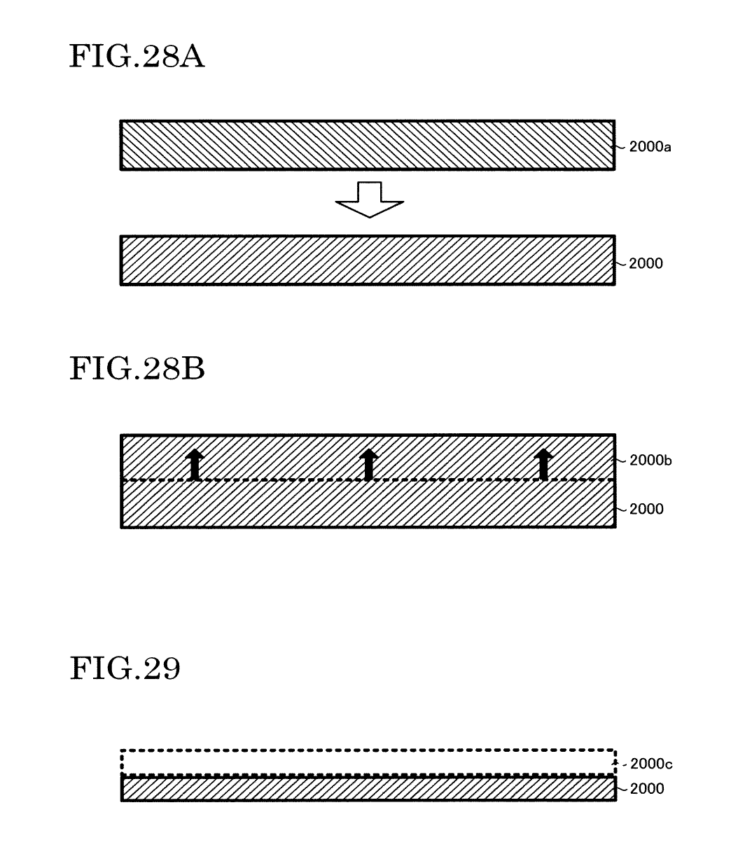

To differentiate the thicknesses of conductive layers between first buildup section (B1) and second buildup section (B2), any other method may be taken. When conductive layer 2000 is made thicker, another conductive film (2000a) may be laminated on conductive layer 2000 as shown in FIG. 28A, for example. Alternatively, as shown in FIG. 28B, for example, conductor (2000b) may be deposited on conductive layer 2000 through plating or the like. Yet alternatively, conductor (2000b) may be grown on conductive layer 2000 through CVD or the like.

When decreasing the thickness of conductive layer 2000, as shown in FIG. 28C, for example, portion (2000c) of conductive layer 2000 may be chemically removed by etching, laser processing or the like. Alternatively, portion (2000c) of conductive layer 2000 may be mechanically shaved by polishing or the like.

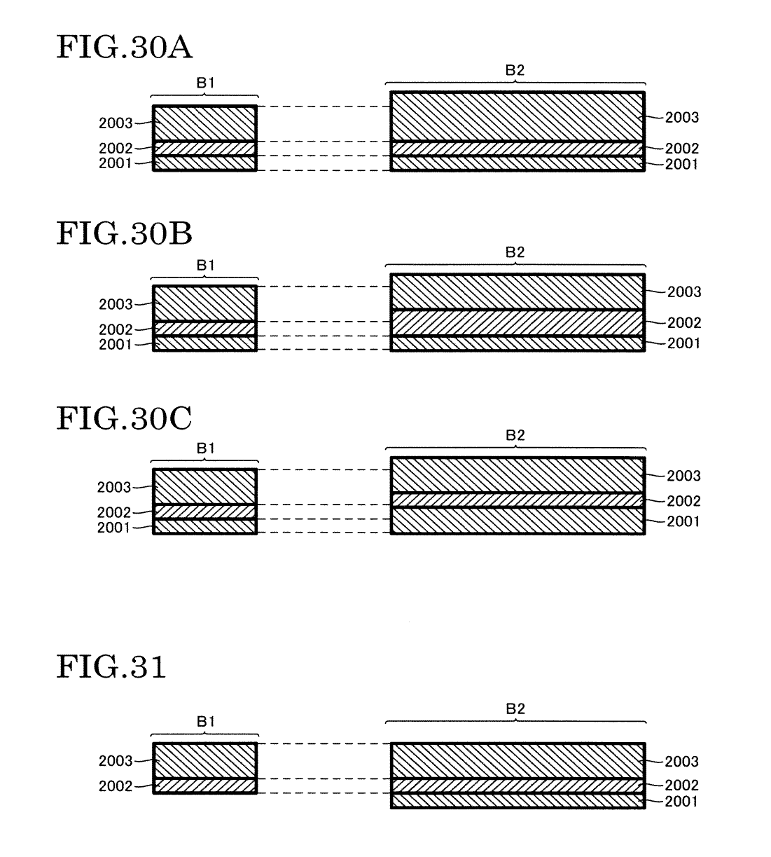

If the conductive layers in first buildup section (B1) and the conductive layers in second buildup section (B2) are each made of copper foil 2001, electroless plated film 2002 and electrolytic plated film 2003, the thickness of electrolytic plated film 2003 may be set different as shown in FIG. 30A, for example; or the thickness of electroless plated film 2002 may be set different as shown in FIG. 30B, for example; or the thickness of copper foil 2001 may be set different as shown in FIG. 30C, for example. Alternatively, as shown in FIG. 31, for example, when the conductive layers in first buildup section (B1) do not include copper foil 2001, the conductive layers in second buildup section (B2) may include copper foil 2001.

In the above embodiment, each insulation layer in first buildup section (B1) (first insulation layer) and each insulation layer in second buildup section (B2) (second insulation layer) all have the same thickness. However, the present invention is not limited to such. For example, it is an option that each insulation layer in first buildup section (B1) may be thicker than any of the insulation layers in second buildup section (B2). Conversely, it is also an option that each insulation layer in second buildup section (B2) may be thicker than any of the insulation layers in first buildup section (B1).

In the above embodiment, each conductive layer in second buildup section (B2) is thicker than any of the conductive layers in first buildup section (B1). However, the present invention is not limited to such.

In the above embodiment, if at least one of the second conductive patterns (conductive patterns (11a˜14a), (11b˜14b)) in the inductor section (inductor unit 10) is thicker than the first conductive patterns (conductive layers 101, 111˜151) formed on the first-surface (F1) side of substrate (100a) (core substrate), ratio W2/W1 is brought closer to 1. Accordingly, wiring board 1000 seldom warps. Also, it is easier to mount electronic component 200 or the like (see FIG. 1) on wiring board 1000 as a result.

In addition, when via conductors (212˜252) in inductor unit 10 (inductor section) in second buildup section (B2) are each made thinner than any of via conductors (112˜152) in first buildup section (B1), it is easier to enhance the quality (Q value) of inductor unit 10 (inductor section) (see FIG. 1).

To suppress warping of wiring board 1000, when tiers at the same ordinal number (in the above embodiment, first tiers, second tiers, third tiers, fourth tiers or fifth tiers) are compared to each other, it is more preferable that the conductive layer in second buildup section (B2) be thinner than the conductive layer in first buildup section (B1) at least in one tier (see FIG. 1).

If at least conductive layer 102 on second surface (F2) of substrate (100a) is thicker than conductive layer 101 on first surface (F1) of substrate (100a), ratio W2/W1 is brought closer to 1, and wiring board 1000 seldom warps. Also, it is easier to mount electronic component 200 or the like (see FIG. 1) on wiring board 1000 as a result.

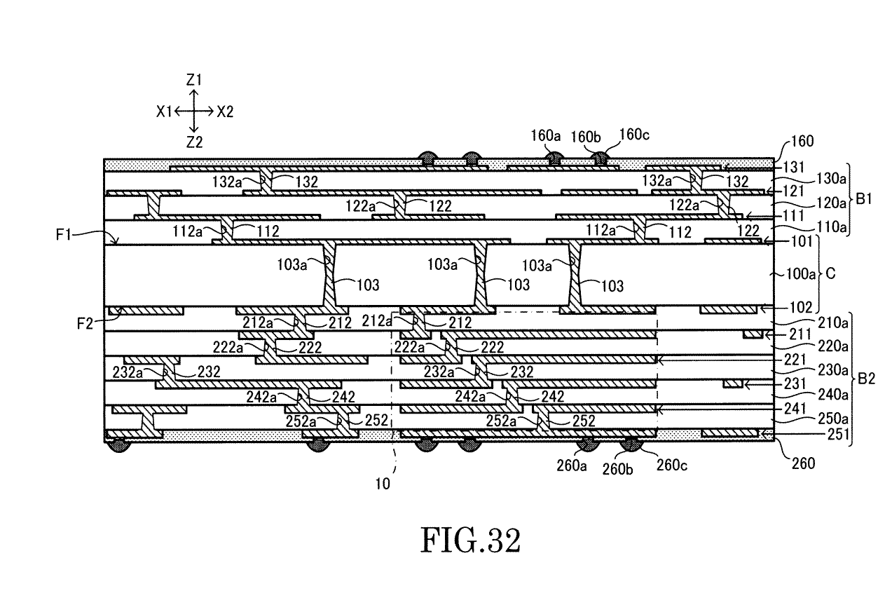

In the above embodiment, the number of tiers is the same in first buildup section (B1) and in second buildup section (B2). However, the number of tiers may be different in both sections. For example, as shown in FIG. 32, the number of tiers in second buildup section (B2) (5, for example) may be greater than the number of tiers in first buildup section (B1) (3, for example). In such a case, when at least one of the conductive layers (211˜251) in second buildup section (B2) is set thicker than any one of the conductive layers (111˜131) in first buildup section (B1), or conductive layer 102 on second surface (F2) of substrate (100a) is set thicker than conductive layer 101 on first surface (F1) of substrate (100a), ratio W2/W1 is brought closer to 1, and wiring board 1000 seldom warps. As a result, it is easier to mount electronic component 200 (see FIG. 1) or the like on wiring board 1000.

The above embodiment has described inductor unit 10, which is formed with first inductor (10a) and second inductor (10b) connected parallel to each other (see FIG. 6). However, the present invention is not limited to such. Inductor unit 10 may be structured with one inductor. Also, the number of turns of first inductor (10a) and second inductor (10b) is not limited to two, and may be any other number. For example, the number of turns may be three or more.

Regarding other factors, the structure of the above wiring board 1000, as well as type, performance, measurements, quality, shapes, number of layers, positioning and so forth of the elements of such a structure, may be modified freely within a scope that does not deviate from the gist of the present invention.

For example, the wiring board may further be multilayered by continuing the buildup process from the state shown previously in FIG. 27.

The material for each conductive layer is not limited to the above, and may be modified according to usage requirements or the like. For example, metal other than copper may be used as the material for conductive layers. The material for via conductors and through-hole conductors is not limited specifically. Also, the material for each insulation layer is not limited specifically. However, as for resins to form interlayer insulation layers, thermosetting resins or thermoplastic resins are preferred. As for thermosetting resins, for example, other than epoxy resin and polyimide, the following may be used: BT resin, allyl polyphenylene ether resin (A-PPE resin) or aramid resin. Also, as for thermoplastic resins, for example, liquid-crystal polymer (LCP), PEEK resin or PTFE resin (fluoro resin) may be used. Such materials are preferred to be selected according to requirements from the viewpoint of, for example, insulation, dielectric properties, heat resistance, mechanical features and so forth. In addition, the above resins may contain additives such as a curing agent, a stabilizer, filler or the like. Alternatively, each conductive layer and each insulation layer may be formed with multiple layers made of different materials.

Each conductor in opening portions (such as via conductors and through-hole conductors) is not limited to being a filled conductor, but may also be a conformal conductor.

The shape of each inductor is not limited to being a spiral form with a substantially rectangular shape when seen in a plan view, and any other form may be employed. For example, it may be a spiral form with a substantially circular shape when seen in a plan view.

The method for manufacturing wiring board 1000 is not limited to the order and contents shown in the above embodiment, and the order and contents may be modified within a scope that does not deviate from the gist of the present invention. Also, some processes may be omitted depending on usage requirements or the like.

For example, the method for forming each conductive layer is not limited specifically. For example, any one or a combination of two or more of the following methods may be used for forming conductive layers: panel plating, pattern plating, full additive, semi-additive (SAP), subtractive, transfer and tenting methods.

In addition, the method for forming each insulation layer (interlayer insulation layer) is not limited specifically. For example, instead of prepreg, a liquid-type or a film-type thermosetting resin or its composites, RCF (resin-coated copper foil) or the like may also be used.

Also, instead of using a laser, wet or dry etching may be used, for example. When etching is employed, the portions not required to be removed are preferred to be protected in advance using a resist or the like.

The above embodiment and modified examples or the like may be combined freely. It is preferred to select an appropriate combination according to usage requirements or the like. Each structure shown in FIGS. 30A-31 may be applied to wiring board 1000 shown in FIG. 1, or to the wiring board shown in FIG. 32.

A wiring board according to an embodiment of the present invention includes the following: a core substrate having a first surface and an opposite second surface; a first conductive pattern formed on the first surface of the core substrate; a first insulation layer formed on the first surface of the core substrate and on the first conductive pattern; a second conductive pattern formed on the second surface of the core substrate; a second insulation layer formed on the second surface of the core substrate and on the second conductive pattern; and an inductor section arranged on the second surface of the core substrate and formed with at least part of the second conductive patterns. In such a wiring board, at least one of the second conductive patterns forming the inductor section is set thicker than the first conductive pattern.

A method for manufacturing a wiring board according to another embodiment of the present invention includes the following: preparing a core substrate having a first surface and an opposite second surface; forming a first conductive pattern on the first surface of the core substrate; forming a first insulation layer on the first surface of the core substrate and on the first conductive pattern; forming a second conductive pattern on the second surface of the core substrate; forming a second insulation layer on the second surface of the core substrate and on the second conductive pattern; and on the second surface of the core substrate, forming an inductor section which is formed with at least part of the second conductive patterns. In such a manufacturing method, at least one of the second conductive patterns forming the inductor section is set thicker than the first conductive pattern.

Obviously, numerous modifications and variations of the present invention are possible in light of the above teachings. It is therefore to be understood that within the scope of the appended claims, the invention may be practiced otherwise than as specifically described herein.

What is claimed is:

1. A wiring board, comprising:
a core structure having a first surface and a second surface on an opposite side of the first surface of the core structure;
a first buildup structure formed on the first surface of the core structure and comprising a plurality of insulation layers and a plurality of conductive layers; and
a second buildup structure formed on the second surface of the core structure and comprising a plurality of insulation layers, a plurality of conductive layers and an inductor device,
wherein the plurality of conductive layers in the second buildup structure includes a plurality of conductive patterns forming the inductor device, and at least one of the conductive patterns forming the inductor device has a thickness which is greater than thicknesses of the conductive layers in the first buildup structure.

2. The wiring board according to claim 1, wherein the core structure includes a core substrate, a first conductive pattern formed on a first surface of the core substrate, and a second conductive pattern formed on a second surface of the core substrate on an opposite side of the first surface of the core substrate, and the inductor device is positioned on the second surface of the core substrate.

3. The wiring board according to claim 1, wherein the inductor device is formed with the plurality of the conductive patterns and a plurality of via conductors formed through the insulation layers in the second buildup structure and connecting the conductive patterns positioned on different layers to each other.

4. The wiring board according to claim 1, wherein the conductive layers in the second buildup structure have thicknesses which are greater than thicknesses of the conductive layers in the first buildup structure.

5. The wiring board according to claim 1, wherein the inductor device is formed in a portion of the second buildup structure such that the portion of the second buildup structure corresponds to a surface portion of the wiring board on which a semiconductor device is mounted.

6. The wiring board according to claim 1, wherein the plurality of conductive patterns of the inductor device is formed in a substantially annular form.

7. The wiring board according to claim 1, wherein the plurality of conductive patterns of the inductor device is formed in a spiral form.

8. The wiring board according to claim 1, wherein each of the conductive patterns forming the inductor device has a substantially U-shaped form or a substantially L-shaped form.

9. The wiring board according to claim 1, wherein each of the insulation layers in the first buildup structure comprises a resin, and each of the insulation layers in the second buildup structure comprises a resin.

10. The wiring board according to claim 1, wherein the conductive layers in the first buildup structure and the conductive layers in the second buildup structure satisfy T2/T1 in a range of approximately 1.5 to approximately 3 where T1 represents thicknesses of the conductive layers in the first buildup structure, and T2 represents thicknesses of the conductive layers in the second buildup structure.

11. The wiring board according to claim 5, wherein the first buildup structure and the second buildup structure satisfy W2/W1 in a range of approximately 0.9 to approximately 1.2 at least in the surface portion for mounting the semiconductor device where W1 represents a volume ratio of the conductive layers in the first buildup structure, and W2 represents a volume ratio of the conductive layers in the second buildup structure.

12. The wiring board according to claim 2, wherein the core structure has a through-hole conductor penetrating through the core substrate and comprising a plating material filling a through hole formed through the core substrate, the first conductive pattern formed on the first surface of the core substrate is connected to the second conductive pattern formed on the second surface of the core substrate by the through-hole conductor.

13. The wiring board according to claim 11, wherein the through-hole conductor has a maximum width which is set at approximately 150 μm or smaller.

14. The wiring board according to claim 1, wherein the inductor device is formed in a plurality, and the plurality of inductor devices are connected in parallel to each other.

15. A method for manufacturing a wiring board, comprising:
preparing a core structure;
forming on a first surface of the core structure a first buildup structure comprising a plurality of insulation layers and a plurality of conductive layers; and
forming on a second surface of the core structure on an opposite side of the first surface of the core structure a second buildup structure comprising a plurality of insulation layers, a plurality of conductive layers and an inductor device,
wherein the forming of the second buildup structure comprises forming the plurality of conductive layers including a plurality of conductive patterns forming the inductor device in the second buildup structure, and at least one of the conductive patterns forming the inductor device has a thickness which is greater than thicknesses of the conductive layers in the first buildup structure.

16. The method for manufacturing a wiring board according to claim 15, wherein the forming of the second buildup structure comprises forming a plurality of via conductors in the insulation layers in the second buildup structure such that the conductive patterns in different layers are connected to each other by the via conductors.

17. The method for manufacturing a wiring board according to claim 15, wherein the conductive layers in the second buildup structure have thicknesses which are greater than thicknesses of the conductive layers in the first buildup structure.

18. The method for manufacturing a wiring board according to claim 15, wherein the forming of the second buildup structure comprises forming the inductor device in a portion of the second buildup structure such that the portion of the second buildup structure corresponds to a surface portion of the wiring board on which a semiconductor device is mounted.

19. The method for manufacturing a wiring board according to claim 15, wherein the forming of the core structure comprises preparing a core substrate having a first surface and a second surface on an opposite side of the first surface of the core substrate, forming a first conductive pattern on the first surface of the core substrate, and forming a second conductive pattern on the second surface of the core substrate, and the forming of the second buildup structure comprises forming on the second surface of the core structure the inductor device with at least a portion of the second conductive pattern.

20. The method for manufacturing a wiring board according to claim 19, wherein the forming of the core structure comprises forming a through hole penetrating through the core substrate, and filling a plating material in the through hole such that a through-hole conductor connecting the first conductive pattern formed on the first surface of the core substrate and the second conductive pattern formed on the second surface of the core substrate is formed through the core substrate.
